(19) United States
(12) Patent Application Publication
(10) Pub. No.: US 2025/0392266 A1
(43) Pub. Date: Dec. 25, 2025

(54) POWER AMPLIFICATION SYSTEM, POWER AMPLIFICATION CIRCUIT, AND POWER AMPLIFICATION METHOD

(71) Applicant: Murata Manufacturing Co., Ltd., Nagaokakyo-shi (JP)

(72) Inventors: Takeshi KOGURE, Nagaokakyo-shi (JP); Ikumi TOKUDA, Nagaokakyo-shi (JP); Kazuaki DEGUCHI, Nagaokakyo-shi (JP); Toshiki MATSUI, Nagaokakyo-shi (JP)

(21) Appl. No.: 19/310,066

(22) Filed: Aug. 26, 2025

Related U.S. Application Data
(63) Continuation of application No. PCT/JP2024/004338, filed on Feb. 8, 2024.

(30) Foreign Application Priority Data
Mar. 6, 2023 (JP) 2023-033668

(51) Int. Cl. H03F 1/32; H03F 3/24; H04B 1/04

(52) U.S. Cl. CPC H03F 1/3258; H03F 3/24; H04B 1/0475; H03F 2200/451; H03F 2201/3224; H04B 2001/0425

(57) ABSTRACT

A power amplification system is provided that includes a power amplifier configured to amplify a first WLAN signal in a first frequency band, a power amplifier configured to amplify a second WLAN signal in a second frequency band higher than the first frequency band, and a circuit configured to pre-distort the second WLAN signal and to not pre-distort the first WLAN signal.

### CROSS REFERENCE TO RELATED APPLICATIONS

This application is a continuation of International Application No. PCT/JP2024/004338, filed Feb. 8, 2024, which claims priority to Japanese Patent Application No. 2023-033668, filed Mar. 6, 2023, the contents of each of which are hereby incorporated by reference in their entireties.

### TECHNICAL FIELD

The present disclosure relates to a power amplification system, a power amplifier circuit, and a power amplification method.

### BACKGROUND

Japanese Unexamined Patent Application Publication No. 2019-140671 discloses a circuit for amplifying 2.4 GHz band signals and 5 GHz band signals of a wireless local area network (WLAN).

Currently, in WLANs, the modulation bandwidth (channel bandwidth) and bit rate of digital modulation methods are increasing, and in the next-generation standard (IEEE 802.11be), adoption of a modulation bandwidth of 320 MHz and a modulation method of 4096 quadrature amplitude modulation (QAM) is planned. As the modulation bandwidth and bit rate of modulation methods increase, a performance index (e.g., error vector magnitude (EVM)) required for communication devices increases, and it is difficult to satisfy the required performance with technologies of the related art, such as that described in Japanese Unexamined Patent Application Publication No. 2019-140671. In addition, it is also desirable for power consumption to be reduced in communication devices.

### SUMMARY OF THE INVENTION

Accordingly, the exemplary aspects of the present disclosure provide a power amplification system, a power amplifier circuit, and a power amplification method that effectively improves the quality of a transmission signal while also suppressing an increase in power consumption.

According to an exemplary embodiment of the present disclosure, a power amplification system is provided that includes a first power amplifier configured to amplify a first wireless local area network signal in a first frequency band, a second power amplifier configured to amplify a second wireless local area network signal in a second frequency band that is higher than the first frequency band, and a first digital pre-distortion circuit configured to pre-distort the second wireless local area network signal and to not pre-distort the first wireless local area network signal.

According to another exemplary embodiment of the present disclosure, a power amplifier circuit is provided that includes a first power amplifier configured to amplify a first wireless local area network signal in a first frequency band, and a second power amplifier configured to amplify a second wireless local area network signal in a second frequency band that is higher than the first frequency band. In this aspect, the second wireless local area network signal is pre-distorted and the first wireless local area network signal is not pre-distorted.

According to another exemplary embodiment of the present disclosure, a power amplification method is provided that includes amplifying a first wireless local area network signal in a first frequency band that is not pre-distorted, pre-distorting a second wireless local area network signal in a second frequency band that is higher than the first frequency band, and amplifying the pre-distorted second wireless local area network signal.

According to the power amplification system, circuit and method of the exemplary embodiments of the present disclosure, the quality of a transmission signal is effectively improved while an increase in power consumption is suppressed.

### BRIEF DESCRIPTION OF DRAWINGS

FIG. 1A is a graph illustrating an example of changes in power supply voltage in an average power tracking (APT) mode.

FIG. 1B is a graph illustrating an example of changes in power supply voltage in an analog envelope tracking (A-ET) mode.

FIG. 1C is a graph illustrating an example of changes in power supply voltage in a digital envelope tracking (D-ET) mode.

FIG. 2 is a circuit configuration diagram of a communication device according to an exemplary embodiment.

FIG. 3 is a circuit configuration diagram of a digital envelope tracker according to an exemplary embodiment.

FIG. 4 is a flowchart illustrating a power amplification method according to an exemplary embodiment.

### DETAILED DESCRIPTION OF EMBODIMENTS

Hereafter, exemplary embodiments of the present disclosure will be described in detail using the drawings. The embodiments described hereinafter each illustrate a comprehensive or specific example of the present disclosure. It is noted that the numerical values, shapes, materials, components, arrangements of the components, the ways in which the components are connected, and so forth described in the following embodiments are merely examples and are not intended to limit the exemplary aspects of the present disclosure.

It is noted that the drawings are schematic drawings in which certain elements are emphasized or omitted or their proportions are adjusted as appropriate in order to illustrate the exemplary aspects of the present disclosure, the drawings are not necessarily illustrated in a strictly accurate manner, and the actual shapes, positional relationships, and proportions may differ from those in the drawings. In the drawings, configurations that are substantially the same as each other may be denoted by the same symbols and repeated description thereof may be omitted or simplified.

In the circuit configuration and for purposes of the present disclosure, it is noted that the meaning of “connected” includes not only direct connections with connection terminals and/or wiring conductors, but also electrical connections realized via other circuit elements. Moreover, the phrase “directly connected” can refer to a direct connection by a connection terminal and/or wiring conductor without the interposition of another circuit element. The phrase “C is connected between A and B” can indicate that one end of C is connected to A and the other end of C is connected to B, and C is arranged in series on a path connecting A and B. The phrase “a path connecting A and B” can refer to a path composed of a conductor electrically connecting A to B.

In the following description, the term “terminal” can refer to a point where a conductor within an element ends. In addition, when the impedance of a conductor between elements is sufficiently low, a terminal is interpreted not only as a single point, but also as any point along the conductor between elements or the entire conductor according to exemplary aspects.

In addition, it is noted that terms indicating the relationships between elements, such as “parallel” and “perpendicular”, terms indicating the shape of elements such as “rectangular”, and numerical ranges do not express only a strict meaning, but rather are intended to include substantially equivalent ranges, for example, differences of about several percent.

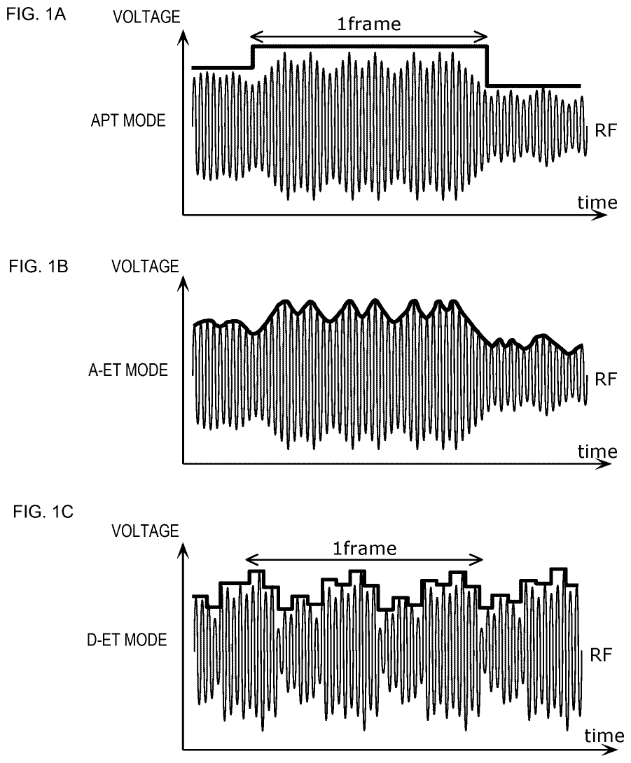

First, as a technology for amplifying a radio-frequency signal with high efficiency, a tracking mode will be described in which a power amplifier is supplied with a power supply voltage that is dynamically adjusted over time based on the radio-frequency signal. Unlike a fixed voltage mode, the tracking mode is a mode in which the power supply voltage applied to the power amplifier is dynamically adjusted. In addition, the fixed voltage mode is a mode in which the power supply voltage applied to the power amplifier is not dynamically adjusted. It is noted that there are several types of tracking modes, but here, the APT mode, the A-ET mode, and the D-ET mode will be described with reference to FIGS. 1A to 1C. In FIGS. 1A to 1C, the horizontal axis represents time and the vertical axis represents voltage. Furthermore, the thick solid line represents the power supply voltage, and the thin solid line (e.g., a waveform) represents the modulated signal.

FIG. 1A is a graph illustrating an example of changes in the power supply voltage in the APT mode. The APT mode is a mode in which the power supply voltage is changed to multiple discrete voltage levels in units of one frame based on the average power.

In an exemplary aspect, a frame can refer to a unit forming a radio-frequency signal (e.g., a modulated signal). For example, in fifth Generation New Radio (5G NR) and Long Term Evolution (LTE), a frame includes ten subframes, each subframe includes multiple slots, and each slot is composed of multiple symbols. The subframe length is 1 milliseconds (ms), and the frame length is 10 ms in the exemplary aspect.

It is noted that a mode in which the voltage level is changed in units of one frame or in units larger than one frame based on the average power is referred to as an APT mode, and is distinguished from a mode in which the voltage level is changed in units smaller than one frame (for example, in units of subframes, slots, or symbols).

FIG. 1B is a graph illustrating an example of changes in the power supply voltage in the A-ET mode. The A-ET mode is a mode in which the power supply voltage is continuously changed based on an envelope signal. In the A-ET mode, the envelope of the modulated signal is tracked.

The envelope signal is a signal that represents the envelope of the modulated signal. The envelope value is expressed, for example, as the square root of (I²+Q²). Here, (I, Q) represent a constellation point. A constellation point is a point that represents a digitally modulated signal on a constellation diagram. (I, Q) are determined, for example, by a baseband integrated circuit (BBIC) based on transmission information.

FIG. 1C is a graph illustrating an example of changes in the power supply voltage in the D-ET mode. The D-ET mode is a mode in which the power supply voltage is changed to multiple discrete voltage levels within one frame based on an envelope signal. In the D-ET mode, the envelope of the modulated signal is tracked.

### EXEMPLARY EMBODIMENTS

Exemplary embodiments are described below.

### [1. Circuit Configuration of Communication Device 60]

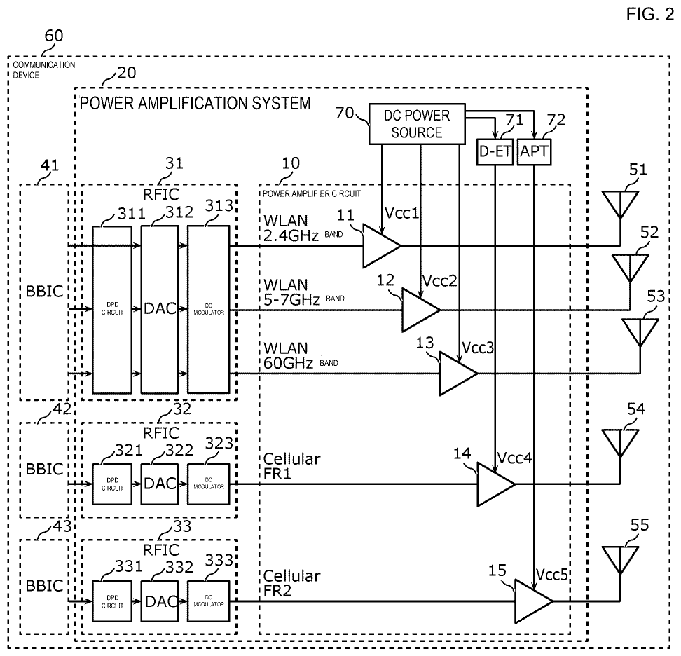

First, the circuit configuration of a communication device 60 according to this embodiment will be described with reference to FIG. 2. FIG. 2 is a circuit configuration diagram of the communication device 60 according to this exemplary embodiment.

It is noted that FIG. 2 is an exemplary circuit configuration, and the communication device 60 can be implemented using any of a wide variety of circuit implementations and circuit technologies. Therefore, the description of the communication device 60 provided below should not be interpreted as being limiting.

According to an exemplary aspect, the communication device 60 according to this embodiment corresponds to user equipment (UE) in a cellular network, and is typically a mobile phone, a smartphone, a tablet computer, a wearable device, or the like. The communication device 60 may be an Internet of Things (IoT) sensor device, a medical/healthcare device, a car, an unmanned aerial vehicle (UAV) (a so-called drone), or an automated guided vehicle (AGV). The communication device 60 may also be configured to function as a base station (BS) in a cellular network.

As illustrated in FIG. 2, the communication device 60 includes a power amplifier circuit 10, radio frequency integrated circuits (RFICs) 31 to 33, BBICs 41 to 43, antennas 51 to 55, a DC power source 70, a digital envelope tracker (D-ET) 71, and an average power tracker (APT) 72. A power amplification system 20 includes the power amplifier circuit 10, the RFICs 31 to 33, the DC power source 70, the digital envelope tracker 71, and the average power tracker 72.

As shown, the power amplifier circuit 10 is connected between the RFICs 31 to 33 and the antennas 51 to 55. The power amplifier circuit 10 is further connected to the DC power source 70, the digital envelope tracker 71, and the average power tracker 72. Specifically, the power amplifier circuit 10 includes power amplifiers 11 to 15.

In an exemplary aspect, the power amplifier 11 is an example of a first power amplifier, and is connected between the RFIC 31 and the antenna 51. The power amplifier 11 is further connected to the DC power source 70, and is supplied with a fixed power supply voltage Vcc1. That is, a fixed voltage mode is applied to the power amplifier 11. This configuration allows the power amplifier 11 to amplify a WLAN 2.4 GHz band radio-frequency signal received from the RFIC 31 using the power supply voltage Vcc1 supplied from the DC power source 70.

In an exemplary aspect, the power amplifier 12 is an example of a second power amplifier, and is connected between the RFIC 31 and the antenna 52. Furthermore, the power amplifier 12 is connected to the DC power source 70, and a fixed power supply voltage Vcc2 is supplied to the power amplifier 12. That is, a fixed voltage mode is applied to the power amplifier 12. This configuration allows the power amplifier 12 to amplify a WLAN 5-7 GHz band radio-frequency signal received from the RFIC 31 using the power supply voltage Vcc2 supplied from the DC power source 70.

In an exemplary aspect, the power amplifier 13 is an example of a third power amplifier, and is connected between the RFIC 31 and the antenna 53. Furthermore, the power amplifier 13 is connected to a DC power source 70 and is supplied with a fixed power supply voltage Vcc3. That is, a fixed voltage mode is applied to the power amplifier 13. This configuration allows the power amplifier 13 to amplify a WLAN 60 GHz band radio-frequency signal received from the RFIC 31 using the power supply voltage Vcc3 supplied from the DC power source 70. It is noted that the power amplifier 13 may be omitted and/or separate from the power amplifier circuit 10 in an exemplary aspect.

In an exemplary aspect, the power amplifier 14 is an example of a fourth power amplifier, and is connected between the RFIC 32 and the antenna 54. Furthermore, the power amplifier 14 is connected to the digital envelope tracker 71 and is supplied with a power supply voltage Vcc4 that dynamically changes to multiple discrete voltages. That is, a D-ET mode is applied to the power amplifier 14. This configuration allows the power amplifier 14 to amplify a radio-frequency signal of a frequency range 1 (FR1) of a cellular network received from the RFIC 32 using the power supply voltage Vcc4 supplied from the digital envelope tracker 71. FR1 is a frequency range of 410 to 7125 MHz, and may be referred to as a Sub-6 band. It is also noted that the power amplifier 14 can be omitted and/or separate from the power amplifier circuit 10 in an exemplary aspect.

In an exemplary aspect, the power amplifier 15 is an example of a fourth power amplifier, and is connected between the RFIC 33 and the antenna 55. The power amplifier 15 is further connected to the average power tracker 72, and is supplied with a power supply voltage Vcc5 that dynamically changes to multiple discrete voltages. That is, an APT mode is applied to the power amplifier 15. This configuration allows the power amplifier 15 to amplify a radio-frequency signal of a frequency range 2 (FR2) of a cellular network received from the RFIC 33 using the power supply voltage Vcc5 supplied from the average power tracker 72. FR2 is a frequency range of 24250 to 52600 MHz, and may be referred to as a millimeter wave band. It is noted that the power amplifier 15 may be omitted and/or separate from the power amplifier circuit 10 in an exemplary aspect.

In an exemplary aspect, the RFICs 31 to 33 are examples of signal processing circuits that process radio-frequency signals (e.g., WLAN signals and cellular network signals). The RFIC 31 can receive digital IQ signals from the BBIC 41 and supply WLAN signals to the power amplifiers 11 to 13. Specifically, the RFIC 31 can supply a 2.4 GHz band WLAN signal (an example of a first WLAN signal) to the power amplifier 11, can supply at least one WLAN signal (an example of a second WLAN signal) in the 5 GHz band, 6 GHz band, or 7 GHz band to the power amplifier 12, and can supply a 60 GHz band WLAN signal (an example of a third WLAN signal) to the power amplifier 13. The RFIC 32 can receive digital IQ signals from the BBIC 42 and supply a cellular network FR1 signal to the power amplifier 14. The RFIC 33 can receive digital IQ signals from the BBIC 43 and supply a cellular network FR2 signal to the power amplifier 15. It is noted that the RFICs 32 and 33 may be omitted and/or separate from the power amplification system 20 in an exemplary aspect.

In an exemplary aspect, the BBICs 41 to 43 are baseband signal processing circuits that perform signal processing using a frequency band that is lower than that of the radio-frequency signals. The BBICs 41 to 43 can digitally modulate, for example, an image signal for image display and/or a bit sequence representing an audio signal for communication via a speaker and generate digital IQ signals. The generated digital IQ signals are supplied to the RFICs 31 to 33. It is noted that the BBICs 41 to 43 may be omitted and/or separate from the communication device 60 in an exemplary aspect.

In an exemplary aspect, the antennas 51 to 55 are configured to transmit the radio-frequency signals amplified by the power amplifier circuit 10 to outside the communication device 60. It is noted that some or all of the antennas 51 to 55 may be omitted from and/or separate the communication device 60 in an exemplary aspect.

In an exemplary aspect, the DC power source 70 can supply a DC voltage to the power amplifiers 11 to 13, the digital envelope tracker 71, and the average power tracker 72. The DC power source 70 may be, for example, a rechargeable battery, but is not limited to this configuration. It is noted the DC power source 70 may be omitted and/or separate from the power amplification system 20 in an exemplary aspect.

In an exemplary aspect, the digital envelope tracker 71 can supply the power supply voltage Vcc4 to the power amplifier 14 in the D-ET mode. Specifically, the digital envelope tracker 71 can generate multiple discrete voltages from the input voltage supplied from the DC power source 70, and selectively supply at least one of the generated discrete voltages to the power amplifier 14. At this time, at least one of the discrete voltages is selected based on the envelope of the FR1 signal of the cellular network. This configuration allows the digital envelope tracker 71 to dynamically change the power supply voltage Vcc4, for example, within one frame, based on the envelope of the FR1 signal of the cellular network. It is noted that the digital envelope tracker 71 may be omitted and/or separate from the power amplification system 20 in an exemplary aspect.

In an exemplary aspect, the average power tracker 72 can supply the power amplifier 15 with the power supply voltage Vcc5 in the APT mode. Specifically, the average power tracker 72 can convert the input voltage supplied from the DC power source 70 into an adjusted voltage and supply the adjusted voltage to the power amplifier 15. At this time, the level of the adjusted voltage is determined based on the average power of the FR2 signal of the cellular network. This configuration allows the average power tracker 72 to dynamically change the power supply voltage Vcc5, for example, in units of one frame or more, based on the average power of the FR2 signal of the cellular network. It is noted that the average power tracker 72 may be omitted and/or separate from the power amplification system 20 in an exemplary aspect.

### [2. Internal Configuration of RFICs 31 to 33]

The internal configurations of the RFICs 31 to 33 will be described with reference to FIG. 2.

The RFIC 31 includes a digital pre-distortion (DPD) circuit 311, a digital-to-analog converter (DAC) 312, and a quadrature modulator 313.

The DPD circuit 311 is an example of a first DPD circuit, and can be configured to pre-distort digital IQ signals supplied from the BBIC 41 using a mathematical model for DPD. For example, the DPD circuit 311 can generate pre-distorted digital IQ signals from the digital IQ signals. The pre-distorted digital IQ signals are supplied to the DAC 312.

Note that the DPD circuit 311 may skip the DPD processing in an exemplary aspect. In this case, the DPD circuit 311 can supply the digital IQ signals supplied from the BBIC 41 (i.e., digital IQ signals that have not been pre-distorted) to the DAC 312.

In this embodiment, the DPD circuit 311 performs DPD processing on the digital IQ signals for WLAN signals in the 5-7 GHz band and the 60 GHz band, and skips DPD processing on the digital IQ signals for WLAN signals in the 2.4 GHz band. In other words, the DPD circuit 311 does not pre-distort a WLAN signal in the 2.4 GHz band, but pre-distorts WLAN signals in the 5-7 GHz band and the 60 GHz band.

The DAC 312 can convert digital IQ signals supplied from the DPD circuit 311 into analog IQ signals. The converted analog IQ signals are supplied to the quadrature modulator 313. It is noted that the DAC 312 can be a conventional DAC according to an exemplary aspect and is not particularly limited.

The quadrature modulator 313 can generate WLAN signals by performing quadrature modulation and up-conversion on analog IQ signals supplied from the DAC 312. The generated WLAN signals are supplied to the power amplifiers 11 to 13. It is noted that the quadrature modulator 313 may be a conventional quadrature modulator according to an exemplary aspect and is not particularly limited.

The RFIC 32 includes a DPD circuit 321, a DAC 322, and a quadrature modulator 323. The RFIC 32 may also include a control unit (not illustrated) that is configured to control the digital envelope tracker 71. Some or all of the functions of the RFIC 32 as a control unit may be implemented outside the RFIC 32 in exemplary aspects.

The DPD circuit 321 is an example of a second DPD circuit, and can be configured to pre-distort digital IQ signals supplied from the BBIC 42 using a mathematical model for DPD. For example, the DPD circuit 321 can generate pre-distorted digital IQ signals from the digital IQ signals. The pre-distorted digital IQ signals are supplied to the DAC 322.

The DAC 322 can convert the digital IQ signal supplied from the DPD circuit 321 into analog IQ signals. The converted analog IQ signals are supplied to the quadrature modulator 323. It is noted that the DAC 322 may be a conventional DAC according to an exemplary aspect and is not particularly limited.

The quadrature modulator 323 can generate the FR1 signal of the cellular network by performing quadrature modulation and up-conversion on the analog IQ signals supplied from the DAC 322. The generated FR1 signal is supplied to the power amplifier 14. It is noted that the quadrature modulator 323 may be a conventional quadrature modulator according to an exemplary aspect and is not particularly limited.

The RFIC 33 includes a DPD circuit 331, a DAC 332, and a quadrature modulator 333. The RFIC 33 may also include a control unit (not illustrated) that is configured to control the average power tracker 72. Some or all of the functions of the RFIC 33 as a control unit may be implemented outside the RFIC 33.

The DPD circuit 331 is an example of a second DPD circuit, and can be configured to pre-distort digital IQ signals supplied from the BBIC 43 using a mathematical model for DPD. For example, the DPD circuit 331 can generate pre-distorted digital IQ signals from the digital IQ signals. The pre-distorted digital IQ signals are supplied to the DAC 332.

The DAC 332 can convert the digital IQ signals supplied from the DPD circuit 331 into analog IQ signals. The converted analog IQ signals are supplied to the quadrature modulator 333. It is noted that the DAC 332 can be a conventional DAC according to an exemplary aspect and is not particularly limited.

The quadrature modulator 333 can generate the FR2 signal of the cellular network by performing quadrature modulation and up-conversion on the analog IQ signals supplied from the DAC 332. The generated FR2 signal is supplied to the power amplifier 15. It is noted that the quadrature modulator 333 may be a conventional quadrature modulator according to an exemplary aspect and is not particularly limited.

The circuit configurations of the RFICs 31 to 33 illustrated in FIG. 2 are merely examples and the RFICs 31 to 33 are not limited to these circuit configurations. For example, some or all of the DPD circuit 311, the DAC 312, and the quadrature modulator 313 may be omitted and/or separate from the RFIC 31 in exemplary aspects. For example, the DPD circuit 311 may be included in the BBIC 41. Similarly, the RFICs 32 and 33 do not necessarily include some or all of the DPD circuit, the DAC, and the quadrature modulator in exemplary aspects.

Next, mathematical models used for DPD in the DPD circuits 311, 321, and 331 will be described. In this embodiment, the mathematical model used for DPD may be a first mathematical model incorporating a memory effect, or a second mathematical model not incorporating a memory effect.

The memory effect is defined as a change in the distortion of a power amplifier caused by a past input signal. Therefore, in the first mathematical model, not only distortion caused by a current input signal, but also a change in distortion caused by a past input signal is modeled. Therefore, nonlinear distortion can be reduced more with the first mathematical model than with the second mathematical model, but the calculation load is increased.

Therefore, in this embodiment, in order to effectively reduce nonlinear distortion with a lower calculation load, the first mathematical model and the second mathematical model are switched therebetween depending on a predetermined condition. For example, the first mathematical model and the second mathematical model are switched therebetween based on the bit rate of the modulation method and/or the modulation bandwidth. The bit rate of the modulation method refers to the number of bits per symbol. For example, the bit rate of 256QAM is 8 bits/symbol. It should be appreciated that switching between the first mathematical model and the second mathematical model is an exemplary aspect and that the first mathematical model or the second mathematical model may be adopted in a fixed manner in alternative exemplary aspects.

Next, a specific example of the second mathematical model not incorporating the memory effect will be described.

$$\begin{matrix}[ Math 1 ] & \\ x [ n ] = {\sum }_{i = 0}^{N - 1} {c}_{i} r [ n ] {\vert r [ n ] \vert}^{i} & ( 1 )\end{matrix}$$

$$x [ n ] : predistorted signal$$

$$r [ n ] : original input signal$$

$${c}_{i} : DPD coefficients$$

$$N : polynomial order$$

The above Equation (1) is an example of a polynomial used in the second mathematical model. The mathematical model using Equation (1) is referred to as a memoryless polynomial model. In Equation (1), for a current input signal r[n], the input signal is multiplied by an exponentiated input signal. The polynomial order N and the DPD coefficient cᵢ are parameters of the memoryless polynomial model, and can be determined experimentally and/or empirically in advance, and are stored in advance in memories (not illustrated) included in, for example, the RFICs 31 to 33.

In Equation (1), when the polynomial order N is increased, it is expected that the nonlinear distortion will be reduced, but there is a concern that the calculation load will be increased. Note that the memory effect is not taken into account in Equation (1), and therefore there is a limit to the reduction of nonlinear distortion in the memoryless polynomial model.

Next, a specific example of a first mathematical model incorporating the memory effect will be described.

$$\begin{matrix}[ Math 2 ] & \\ x [ n ] = {\sum }_{i = 0}^{N - 1} {\sum }_{q = 0}^{Q} {c}_{qi} r [ n - q ] {\vert r [ n - q ] \vert}^{2} & ( 2 )\end{matrix}$$

$$x [ n ] : predistorted signal$$

$$r [ n ] : original input signal$$

$${c}_{qi} : DPD coefficients$$

$$Q : memory depth$$

$$N : polynomial order$$

The above Equation (2) is an example of a polynomial used in the first mathematical model. The mathematical model using Equation (2) is referred to as a memory polynomial model (MPM). In Equation (2), for each of the input signals r[n−q] from past Q to present 0, the input signal is multiplied by an exponentiated input signal. The polynomial order N, memory depth Q, and DPD coefficient c_{qi} are parameters of the MPM and can be determined in advance experimentally and/or empirically, and are stored in advance in memories (not illustrated) included in the RFICs 31 to 33, for example.

In Equation (2), when the polynomial order N and memory depth Q are increased, it is expected that nonlinear distortion will be reduced, but there are concerns about an increase in the number of parameters, an increase in the calculation load, and a decrease in convergence when the DPD coefficient c_{qi} is determined.

$$\begin{matrix}[ Math 3 ] & \\ x [ n ] = {\sum }_{i = 0}^{N - 1} {\sum }_{q = 0}^{Q} {c}_{qi} r [ n - q ] {\vert r [ n - q ] \vert}^{i} + & ( 3 - 1 ) ( 3 )\end{matrix}$$

$${\sum }_{i = 1}^{{N}_{d}} {\sum }_{m = 1}^{{M}_{d}} {\sum }_{q = 0}^{{Q}_{d}} {d}_{qmi} r [ n - q ] {\vert r [ n - q - m ] \vert}^{i} + \qquad ( 3 - 2 )$$

$${\sum }_{i = 1}^{{N}_{e}} {\sum }_{m = 1}^{{M}_{e}} {\sum }_{q = 0}^{{Q}_{e}} {e}_{qmi} r [ n - q ] {\vert r [ n - q + m ] \vert}^{i} \qquad ( 3 - 3 )$$

$$x [ n ] : predistorted signal$$

$$r [ n ] : original input signal$$

$${c}_{qi} , {d}_{qmi} , {e}_{qmi} : DPD coefficients$$

$$Q : sync memory depth$$

$$N : sync order$$

$${Q}_{d} : lag memory depth$$

$${M}_{d} : maximum lag$$

$${N}_{d} : lag order$$

$${Q}_{e} : lead memory depth$$

$${M}_{e} : maximum lead$$

$${N}_{e} : lead order$$

The above Equation (3) is an example of a polynomial used in the first mathematical model. The mathematical model in which Equation (3) is used is referred to as a generalized memory polynomial model (GMP). In Equation (3), a sync term (3-1) is combined with a lag term (3-2) and a lead term (3-3). The sync term (3-1) is the same as the term in Equation (2) for MPM. In the lag term (3-2), the input signal is multiplied by an exponentiated past input signal. In the lead term (3-3), the input signal is multiplied by an exponentiated future input signal. The orders N, N_{d}, and Nₑ, the memory depth Q, and the DPD coefficients c_{qi}, d_{qmi}, and e_{qmi} of the respective terms are parameters of the GMP, and can be determined experimentally and/or empirically in advance, and are stored in advance in memories (not illustrated) included in the RFICs 31 to 33, for example.

In Equation (3), when the memory depths Q, Q_{d}, Qₑ and the cross widths M_{d} and Mₑ of the respective terms are increased, it is expected that the nonlinear distortion will be reduced. However, there are concerns about an increase in the number of parameters, an increase in the calculation load, and a decrease in convergence when the DPD coefficients c_{qi}, d_{qmi}, and e_{qmi} are determined.

The effect of reducing nonlinear distortion increases in the order of the memoryless polynomial model, the MPM, and the GMP, but the number of parameters increases and the calculation load (i.e., power consumption) also increases. In other words, the GMP can reduce nonlinear distortion more than the MPM and the memoryless polynomial model, and the MPM can reduce nonlinear distortion more than the memoryless polynomial model. Conversely, the memoryless polynomial model can reduce the calculation load more than the MPM and GMP, and the MPM can reduce the calculation load more than the GMP. Furthermore, the memoryless polynomial model can reduce the amount of memory used for storing parameters more than the MPM and GMP, and the MPM can reduce the amount of memory used for storing parameters more than the GMP.

Note that the first mathematical model is not limited to the MPM and GMP. That is, the first mathematical model may use a mathematical expression other than the above Equations (2) and (3) in alternative exemplary aspects. Furthermore, the second mathematical model is not limited to the memoryless polynomial model. That is, the second mathematical model may use a mathematical expression other than the above Equation (1) in alternative exemplary aspects.

### [3. Circuit Configuration of Digital Envelope Tracker 71]

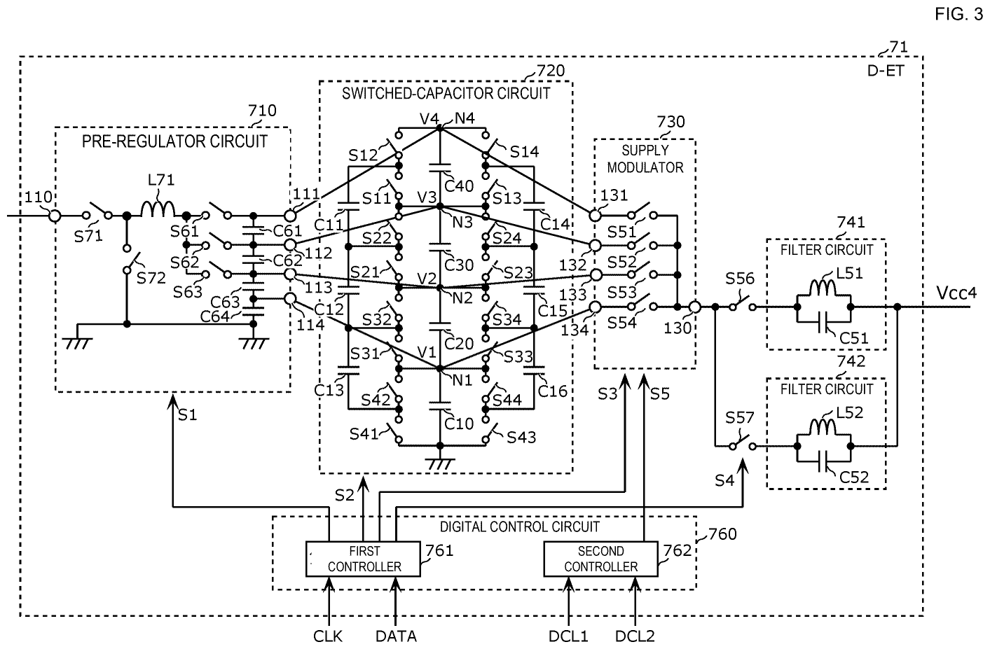

Next, the circuit configuration of the digital envelope tracker 71 will be described with reference to FIG. 3. FIG. 3 is a circuit configuration diagram of the digital envelope tracker 71 according to this embodiment.

Note that FIG. 3 illustrates an exemplary circuit configuration, and the digital envelope tracker 71 may be implemented using any of a wide variety of circuit implementations and circuit technologies. Therefore, the description of the digital envelope tracker 71 provided below should not be interpreted as limiting.

In this exemplary aspect, the digital envelope tracker 71 includes a pre-regulator circuit 710, a switched-capacitor circuit 720, a supply modulator 730, filter circuits 741 and 742, switches S56 and S57, and a digital control circuit 760.

The pre-regulator circuit 710 can convert an input voltage supplied from a DC power source (not illustrated) to an adjusted voltage using a power inductor. The pre-regulator circuit 710 includes a power inductor and switches. The power inductor is an inductor used to step up and/or step down a direct current (DC) voltage. The power inductor is arranged in series with a DC path. The power inductor may be connected between the DC path and ground (i.e., arranged in parallel with the DC path). Such a pre-regulator circuit 710 may also be referred to as a magnetic regulator or a DC/DC converter. It is noted that the pre-regulator circuit 710 does not necessarily include a power inductor in an exemplary aspect.

The switched-capacitor circuit 720 includes a plurality of capacitors and a plurality of switches, and can generate a plurality of discrete voltages, which have a plurality of discrete voltage levels, from the voltage supplied from the pre-regulator circuit 710. The switched-capacitor circuit 720 may also be referred to as a switched-capacitor voltage ladder.

The supply modulator 730 can selectively output at least one of the plurality of discrete voltages generated by the switched-capacitor circuit 720 to the power amplifier 14.

The filter circuits 741 and 742 can attenuate noise from the plurality of discrete voltages supplied to the power amplifier 14. The filter circuits 741 and 742 may also be referred to as pulse shaping networks or transition shaping filters.

The switches S56 and S57 are on/off switches for the filter circuits 741 and 742, respectively. The switch S56 is connected between the supply modulator 730 and the filter circuit 741. The switch S57 is connected between the supply modulator 730 and the filter circuit 742.

The digital control circuit 760 can control the pre-regulator circuit 710, the switched-capacitor circuit 720, the supply modulator 730, and the switches S56 and S57 based on digital control signals from the RFIC 32.

It is noted that the digital envelope tracker 71 does not necessarily include all of the pre-regulator circuit 710, the switched-capacitor circuit 720, the supply modulator 730, the filter circuits 741 and 742, the switches S56 and S57, and the digital control circuit 760. For example, the digital envelope tracker 71 may omit the pre-regulator circuit 710 in an exemplary aspect. In addition, for example, the digital envelope tracker 71 may omit the filter circuits 741 and 742, and the switches S56 and S57 in exemplary aspects. Furthermore, any combination of the pre-regulator circuit 710, the switched-capacitor circuit 720, the supply modulator 730, the filter circuits 741 and 742, and the switches S56 and S57 may be integrated into a single circuit. In addition, the digital envelope tracker 71 may include multiple pre-regulator circuits instead of the pre-regulator circuit 710 and the switched-capacitor circuit 720. In this case, the supply modulator 730 may be configured to select at least one of the multiple pre-regulator circuits.

Next, the circuit configuration of each circuit included in the digital envelope tracker 71 will be described with reference to FIG. 3.

### [3.1. Circuit Configuration of Switched-Capacitor Circuit 720]

First, the circuit configuration of the switched-capacitor circuit 720 will be described. The switched-capacitor circuit 720 includes capacitors C11 to C16, capacitors C10, C20, C30, and C40, and switches S11 to S14, S21 to S24, S31 to S34, and S41 to S44. Energy and charge are input from the pre-regulator circuit 710 to the switched-capacitor circuit 720 at nodes N1 to N4 and are extracted from the switched-capacitor circuit 720 to the supply modulator 730 at the nodes N1 to N4.

Each of the capacitors C11 to C16 can be configured to function as a flying capacitor (sometimes referred to as a transfer capacitor). That is, each of the capacitors C11 to C16 is used to step up or step down the adjusted voltage supplied from the pre-regulator circuit 710. More specifically, the capacitors C11 to C16 can be configured to transfer charges between the capacitors C11 to C16 and the nodes N1 to N4 so that voltages V1 to V4 (voltages relative to the ground potential) that satisfy V1:V2:V3:V4=1:2:3:4 are maintained at the four nodes N1 to N4. These voltages V1 to V4 correspond to a plurality of discrete voltages having a plurality of discrete voltage levels.

The capacitor C11 has two electrodes. One of the two electrodes of the capacitor C11 is connected to one end of the switch S11 and one end of the switch S12. The other of the two electrodes of the capacitor C11 is connected to one end of the switch S21 and one end of the switch S22.

The capacitor C12 has two electrodes. One of the two electrodes of the capacitor C12 is connected to one end of the switch S21 and one end of the switch S22. The other of the two electrodes of the capacitor C12 is connected to one end of the switch S31 and one end of the switch S32.

The capacitor C13 has two electrodes. One of the two electrodes of the capacitor C13 is connected to one end of the switch S31 and one end of the switch S32. The other of the two electrodes of the capacitor C13 is connected to one end of the switch S41 and one end of the switch S42.

The capacitor C14 has two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 has two electrodes. One of the two electrodes of the capacitor C15 is connected to one end of the switch S23 and one end of the switch S24. The other of the two electrodes of the capacitor C15 is connected to one end of the switch S33 and one end of the switch S34.

The capacitor C16 has two electrodes. One of the two electrodes of the capacitor C16 is connected to one end of the switch S33 and one end of the switch S34. The other of the two electrodes of the capacitor C16 is connected to one end of the switch S43 and one end of the switch S44.

The set of the capacitors C11 and C14, the set of the capacitors C12 and C15, and the set of the capacitors C13 and C16 can be charged and discharged in a complementary manner by repeating a first phase and a second phase.

Specifically, in the first phase, the switches S12, S13, S22, S23, S32, S33, S42, and S43 are turned on. As a result, for example, one of the two electrodes of the capacitor C12 is connected to the node N3, the other of the two electrodes of the capacitor C12 and one of the two electrodes of the capacitor C15 are connected to the node N2, and the other of the two electrodes of the capacitor C15 is connected to the node N1.

On the other hand, in the second phase, the switches S11, S14, S21, S24, S31, S34, S41, and S44 are turned on. As a result, for example, one of the two electrodes of the capacitor C15 is connected to the node N3, the other of the two electrodes of the capacitor C15 and one of the two electrodes of the capacitor C12 are connected to the node N2, and the other of the two electrodes of the capacitor C12 is connected to the node N1.

By repeating the first phase and the second phase, for example, when one of the capacitors C12 and C15 is being charged from the node N2, the other of the capacitors C12 and C15 can be discharged to the capacitor C30. That is, the capacitors C12 and C15 can be configured to be charged and discharged in a complementary manner.

By repeating the first phase and the second phase, each of the set of the capacitors C11 and C14 and the set of the capacitors C13 and C16 can be charged and discharged in a complementary manner, similarly to the set of the capacitors C12 and C15.

Each of the capacitors C10, C20, C30, and C40 can be configured to function as a smoothing capacitor in an exemplary aspect. That is, each of the capacitors C10, C20, C30, and C40 is used to hold and smooth the voltages V1 to V4 at the nodes N1 to N4.

The capacitor C10 is connected between the node N1 and the ground. Specifically, one of the two electrodes of the capacitor C10 is connected to the node N1. Meanwhile, the other of the two electrodes of the capacitor C10 is connected to the ground.

The capacitor C20 is connected between the nodes N2 and N1. Specifically, one of the two electrodes of the capacitor C20 is connected to the node N2. Meanwhile, the other of the two electrodes of the capacitor C20 is connected to the node N1.

The capacitor C30 is connected between the nodes N3 and N2. Specifically, one of the two electrodes of the capacitor C30 is connected to the node N3. Meanwhile, the other of the two electrodes of the capacitor C30 is connected to the node N2.

The capacitor C40 is connected between the nodes N4 and N3. Specifically, one of the two electrodes of the capacitor C40 is connected to the node N4. Meanwhile, the other of the two electrodes of the capacitor C40 is connected to the node N3.

The switch S11 is connected between one of the two electrodes of the capacitor C11 and the node N3. Specifically, one end of the switch S11 is connected to one of the two electrodes of the capacitor C11. Meanwhile, the other end of the switch S11 is connected to the node N3.

The switch S12 is connected between one of the two electrodes of the capacitor C11 and the node N4. Specifically, one end of the switch S12 is connected to one of the two electrodes of the capacitor C11. Meanwhile, the other end of the switch S12 is connected to the node N4.

The switch S21 is connected between one of the two electrodes of the capacitor C12 and the node N2. Specifically, one end of the switch S21 is connected to one of the two electrodes of the capacitor C12 and the other of the two electrodes of the capacitor C11. Meanwhile, the other end of the switch S21 is connected to the node N2.

The switch S22 is connected between one of the two electrodes of the capacitor C12 and the node N3. Specifically, one end of the switch S22 is connected to one of the two electrodes of the capacitor C12 and the other of the two electrodes of the capacitor C11. Meanwhile, the other end of the switch S22 is connected to the node N3.

The switch S31 is connected between the other of the two electrodes of the capacitor C12 and the node N1. Specifically, one end of the switch S31 is connected to the other of the two electrodes of the capacitor C12 and one of the two electrodes of the capacitor C13. Meanwhile, the other end of the switch S31 is connected to the node N1.

The switch S32 is connected between the other of the two electrodes of the capacitor C12 and the node N2. Specifically, one end of the switch S32 is connected to the other of the two electrodes of the capacitor C12 and one of the two electrodes of the capacitor C13. Meanwhile, the other end of the switch S32 is connected to the node N2. That is, the other end of the switch S32 is connected to the other end of the switch S21.

The switch S41 is connected between the other of the two electrodes of the capacitor C13 and the ground. Specifically, one end of the switch S41 is connected to the other of the two electrodes of the capacitor C13. Meanwhile, the other end of the switch S41 is connected to the ground.

The switch S42 is connected between the other of the two electrodes of the capacitor C13 and the node N1. Specifically, one end of the switch S42 is connected to the other of the two electrodes of the capacitor C13. Meanwhile, the other end of the switch S42 is connected to the node N1. That is, the other end of the switch S42 is connected to the other end of the switch S31.

The switch S13 is connected between one of the two electrodes of the capacitor C14 and the node N3. Specifically, one end of the switch S13 is connected to one of the two electrodes of the capacitor C14. Meanwhile, the other end of the switch S13 is connected to the node N3. That is, the other end of the switch S13 is connected to the other end of the switch S11 and the other end of the switch S22.

The switch S14 is connected between one of the two electrodes of the capacitor C14 and the node N4. Specifically, one end of the switch S14 is connected to one of the two electrodes of the capacitor C14. Meanwhile, the other end of the switch S14 is connected to the node N4. That is, the other end of the switch S14 is connected to the other end of the switch S12.

The switch S23 is connected between one of the two electrodes of the capacitor C15 and the node N2. Specifically, one end of the switch S23 is connected to one of the two electrodes of the capacitor C15 and the other of the two electrodes of the capacitor C14. Meanwhile, the other end of the switch S23 is connected to the node N2. That is, the other end of the switch S23 is connected to the other end of the switch S21 and the other end of the switch S32.

The switch S24 is connected between one of the two electrodes of the capacitor C15 and the node N3. Specifically, one end of the switch S24 is connected to one of the two electrodes of the capacitor C15 and the other of the two electrodes of the capacitor C14. Meanwhile, the other end of the switch S24 is connected to the node N3. That is, the other end of the switch S24 is connected to the other end of the switch S11, the other end of the switch S22, and the other end of the switch S13.

The switch S33 is connected between the other of the two electrodes of the capacitor C15 and the node N1. Specifically, one end of the switch S33 is connected to the other of the two electrodes of the capacitor C15 and one of the two electrodes of the capacitor C16. Meanwhile, the other end of the switch S33 is connected to the node N1. That is, the other end of the switch S33 is connected to the other end of the switch S31 and the other end of the switch S42.

The switch S34 is connected between the other of the two electrodes of the capacitor C15 and the node N2. Specifically, one end of the switch S34 is connected to the other of the two electrodes of the capacitor C15 and one of the two electrodes of the capacitor C16. Meanwhile, the other end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and the ground. Specifically, one end of the switch S43 is connected to the other of the two electrodes of the capacitor C16. Meanwhile, the other end of the switch S43 is connected to the ground.

The switch S44 is connected between the other of the two electrodes of the capacitor C16 and the node N1. Specifically, one end of the switch S44 is connected to the other of the two electrodes of the capacitor C16. Meanwhile, the other end of the switch S44 is connected to the node N1. That is, the other end of the switch S44 is connected to the other end of the switch S31, the other end of the switch S42, and the other end of the switch S33.

A first set of switches including the switches S12, S13, S22, S23, S32, S33, S42, and S43, and a second set of switches including the switches S11, S14, S21, S24, S31, S34, S41, and S44 are switched on and off in a complementary manner based on a control signal S2. Specifically, in the first phase, the first set of switches are turned on, and the second set of switches are turned off. Conversely, in the second phase, the first set of switches are turned off, and the second set of switches are turned on.

For example, in one of the first phase and the second phase, the capacitors C10 to C40 are charged from the capacitors C11 to C13, and in the other of the first phase and the second phase, the capacitors C10 to C40 are charged from the capacitors C14 to C16. That is, since the capacitors C10 to C40 are always charged from the capacitors C11 to C13 or the capacitors C14 to C16, even when a current rapidly flows from the nodes N1 to N4 to the supply modulator 730, the nodes N1 to N4 are rapidly replenished with charge, so that potential fluctuations at the nodes N1 to N4 are suppressed.

By operating in this manner, the switched-capacitor circuit 720 can be configured to maintain approximately equal voltages at both ends of each of the capacitors C10, C20, C30, and C40. Specifically, at the four nodes labeled V1 to V4, voltages V1 to V4 (voltages relative to ground potential) that satisfy V1:V2:V3:V4=1:2:3:4 are maintained. The voltage levels of the voltages V1 to V4 correspond to a plurality of discrete voltage levels that can be supplied to the supply modulator 730 by the switched-capacitor circuit 720.

It is noted that the voltage ratio (V1:V2:V3:V4) is not limited to (1:2:3:4). For example, the voltage ratio (V1:V2:V3:V4) may be (1:2:4:8) in an alternative exemplary aspect.

Note that the configuration of the switched-capacitor circuit 720 illustrated in FIG. 3 is merely an example, and the configuration is not limited to this example. In FIG. 3, the switched-capacitor circuit 720 is configured to supply four discrete voltages, but the number of discrete voltages is not limited to this. The switched-capacitor circuit 720 may be configured to supply any number of two or more discrete voltages. For example, when two discrete voltages are supplied, it is sufficient that the switched-capacitor circuit 720 includes at least the capacitors C12 and C15, and the switches S21 to S24 and S31 to S34.

### [3.2. Circuit Configuration of Supply Modulator 730]

Next, the circuit configuration of the supply modulator 730 will be described. The supply modulator 730 includes input terminals 131 to 134, switches S51 to S54, and an output terminal 130.

The output terminal 130 is connected to the filter circuits 741 and 742. The output terminal 130 is a terminal for supplying a power supply voltage selected from the voltages V1 to V4 to the power amplifier 14 via the filter circuit 741 and/or the filter circuit 742.

The input terminals 131 to 134 are respectively connected to the nodes N4 to N1 of the switched-capacitor circuit 720. The input terminals 131 to 134 are terminals for receiving the voltages V4 to V1 from the switched-capacitor circuit 720.

The switch S51 is connected between the input terminal 131 and the output terminal 130. Specifically, the switch S51 has a terminal that is connected to the input terminal 131 and a terminal that is connected to the output terminal 130. In this connection configuration, the switch S51 can be switched between connecting and not connecting the input terminal 131 and the output terminal 130 to each other by being switched on/off by a control signal S3.

The switch S52 is connected between the input terminal 132 and the output terminal 130. Specifically, the switch S52 has a terminal connected to the input terminal 132 and a terminal connected to the output terminal 130. In this connection configuration, the switch S52 can be switched between connecting and not connecting the input terminal 132 and the output terminal 130 to each other by being switched on/off by the control signal S3.

The switch S53 is connected between the input terminal 133 and the output terminal 130. Specifically, the switch S53 has a terminal connected to the input terminal 133 and a terminal connected to the output terminal 130. In this connection configuration, the switch S53 can be switched between connecting and not connecting the input terminal 133 and the output terminal 130 to each other by being switched on/off by the control signal S3.

The switch S54 is connected between the input terminal 134 and the output terminal 130. Specifically, the switch S54 has a terminal connected to the input terminal 134 and a terminal connected to the output terminal 130. In this connection configuration, the switch S54 can be switched between connecting and not connecting the input terminal 134 and the output terminal 130 to each other by being switched on/off by the control signal S3.

These switches S51 to S54 are controlled to be switched on in an exclusive manner. That is, only one of the switches S51 to S54 is switched on, and the remaining switches of the switches S51 to S54 are switched off. This configuration allows the supply modulator 730 to output one voltage selected from the voltages V1 to V4.

Note that the configuration of the supply modulator 730 illustrated in FIG. 3 is an example and is not limited to this example. In particular, the switches S51 to S54 may have any configuration as long as they can be configured to selectively connect at least one of the four input terminals 131 to 134 to the output terminal 130. For example, the supply modulator 730 may further include a switch connected between the switches S51 to S53 and the switch S54 and output terminal 130. For example, the supply modulator 730 may further include a switch connected between the switches S51 and S52 and the switches S53 and S54 and output terminal 130.

When voltages of two discrete voltage levels are supplied from the switched-capacitor circuit 720, it is sufficient that the supply modulator 730 includes at least two of the switches S51 to S54.

### [3.3. Circuit Configuration of Pre-Regulator Circuit 710]

Next, the circuit configuration of the pre-regulator circuit 710 will be described. The pre-regulator circuit 710 includes an input terminal 110, output terminals 111 to 114, switches S61 to S63, S71, and S72, a power inductor L71, and capacitors C61 to C64.

The input terminal 110 is an input terminal for a DC voltage. In other words, the input terminal 110 is a terminal for receiving an input voltage from the DC power source 70.

The output terminal 111 is an output terminal for the voltage V4. That is, the output terminal 111 is a terminal for supplying the voltage V4 to the switched-capacitor circuit 720. The output terminal 111 is connected to the node N4 of the switched-capacitor circuit 720.

The output terminal 112 is an output terminal for the voltage V3. That is, the output terminal 112 is a terminal for supplying the voltage V3 to the switched-capacitor circuit 720. The output terminal 112 is connected to the node N3 of the switched-capacitor circuit 720.

The output terminal 113 is an output terminal for the voltage V2. That is, the output terminal 113 is a terminal for supplying the voltage V2 to the switched-capacitor circuit 720. The output terminal 113 is connected to the node N2 of the switched-capacitor circuit 720.

The output terminal 114 is an output terminal for the voltage V1. That is, the output terminal 114 is a terminal for supplying the voltage V1 to the switched-capacitor circuit 720. The output terminal 114 is connected to the node N1 of the switched-capacitor circuit 720.

The switch S71 is connected between the input terminal 110 and one end of the power inductor L71. Specifically, the switch S71 has a terminal connected to the input terminal 110 and a terminal connected to one end of the power inductor L71. In this connection configuration, the switch S71 can switch between connecting and not connecting the input terminal 110 and one end of the power inductor L71 to each other by being switched between being open and closed based on a control signal S1.

The switch S72 is connected between one end of the power inductor L71 and the ground. Specifically, the switch S72 has a terminal connected to one end of the power inductor L71 and a terminal connected to the ground. In this connection configuration, the switch S72 can switch between connecting and not connecting the one end of the power inductor L71 and the ground to each other by being switched between being open and closed based on the control signal S1.

The switch S61 is connected between the other end of the power inductor L71 and the output terminal 111. Specifically, the switch S61 has a terminal connected to the other end of the power inductor L71 and a terminal connected to the output terminal 111. In this connection configuration, the switch S61 can switch between connecting and not connecting the other end of the power inductor L71 and the output terminal 111 to each other by being switched between being open and closed based on the control signal S1.

The switch S62 is connected between the other end of the power inductor L71 and the output terminal 112. Specifically, the switch S62 has a terminal connected to the other end of the power inductor L71 and a terminal connected to the output terminal 112. In this connection configuration, the switch S62 can switch between connecting and not connecting the other end of the power inductor L71 and the output terminal 112 by being switched between being open and closed based on the control signal S1.

The switch S63 is connected between the other end of the power inductor L71 and the output terminal 113. Specifically, the switch S63 has a terminal connected to the other end of the power inductor L71 and a terminal connected to the output terminal 113. In this connection configuration, the switch S63 can switch between connecting and not connecting the other end of the power inductor L71 and the output terminal 113 to each other by being switched between being open and closed based on the control signal S1.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62.

One of the two electrodes of the capacitor C62 is connected to the switch S62, the output terminal 112, and the other of the two electrodes of the capacitor C61. The other of the two electrodes of the capacitor C62 is connected to a path connecting the switch S63, the output terminal 113, and one of the two electrodes of the capacitor C63 to each other.

One of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

One of the two electrodes of the capacitor C64 is connected to the output terminal 114 and the other of the two electrodes of the capacitor C63. The other of the two electrodes of the capacitor C64 is connected to ground.

The switches S61 to S63 are controlled to be switched on in an exclusive manner. That is, only one of the switches S61 to S63 is switched on, and the remaining switches of the switches S61 to S63 are switched off. By switching on only one of the switches S61 to S63, the pre-regulator circuit 710 can change the voltage supplied to the switched-capacitor circuit 720 between the voltage levels of the voltages V2 to V4.

The thus-configured pre-regulator circuit 710 can supply charge to the switched-capacitor circuit 720 via at least one of the output terminals 111 to 114.

When the input voltage only needs to be converted into one adjusted voltage, it is sufficient that the pre-regulator circuit 710 includes at least the switches S71 and S72 and the power inductor L71.

### [3.4. Circuit Configurations of Filter Circuits 741 and 742]

Next, the circuit configurations of the filter circuits 741 and 742 will be described.

The filter circuit 741 includes a parallel circuit (e.g., an LC parallel circuit) including an inductor L51 and a capacitor C51. One end of the parallel circuit including the inductor L51 and the capacitor C51 is connected to the switch S56, and the other end of the parallel circuit including the inductor L51 and the capacitor C51 is connected to the power amplifier 14.

The filter circuit 742 includes a parallel circuit including an inductor L52 and a capacitor C52. One end of the parallel circuit including the inductor L52 and the capacitor C52 is connected to the switch S57, and the other end of the parallel circuit including the inductor L52 and the capacitor C52 is connected to the power amplifier 14.

The filter circuits 741 and 742 connected in this manner are switched on/off by the switches S56 and S57. This configuration allows the filter circuits 741 and 742 to switch on/off band-elimination filters for eliminating noise from a plurality of discrete voltages. For example, by controlling the opening and closing of the switches S56 and S57, three types of band-elimination filters described below in (1) to (3) can be realized.

When the switch S56 is closed and the switch S57 is open, the filter circuit 741 is connected between the supply modulator 730 and the power amplifier 14, and the filter circuit 742 is not connected therebetween. As a result, the filter circuit 741 can be configured to function as a band-elimination filter, and the filter circuit 742 does not function as a band-elimination filter.

When the switch S56 is open and the switch S57 is closed, the filter circuit 742 is connected between the supply modulator 730 and the power amplifier 14, and the filter circuit 741 is not connected therebetween. As a result, the filter circuit 742 can be configured to function as a band-elimination filter, and the filter circuit 741 does not function as a band-elimination filter.

When the switch S56 is closed and the switch S57 is closed, the filter circuits 741 and 742 are connected between the supply modulator 730 and the power amplifier 14. As a result, the filter circuits 741 and 742 can be configured to function as band-elimination filters.

Such opening and closing of the switches S56 and S57 can be controlled based on, for example, the modulation bandwidth of the FR1 signal. In addition, when the power amplifier 14 is configured to amplify transmission signals of multiple frequency bands, the opening and closing of the switches S56 and S57 may be controlled based on the frequency band of the transmission signal amplified by the power amplifier 14. Note that the control of the opening and closing of the switches S56 and S57 is not limited to the above description.

The circuit configurations of the filter circuits 741 and 742 illustrated in FIG. 3 are examples and are not limited to these examples. For example, the filter circuit 741 and/or the filter circuit 742 may be a series circuit (e.g., an LC series circuit) including an inductor and a capacitor. In this case, the LC series circuit may be connected between the path connecting the supply modulator 730 and the power amplifier 14, and the ground.

### [3.5. Circuit Configuration of Digital Control Circuit 760]

Next, the circuit configuration of the digital control circuit 760 will be described. The digital control circuit 760 includes a first controller 761 and a second controller 762.

The first controller 761 can be configured to perform processing on a serial data signal (DATA) based on a clock signal (CLK) supplied from the RFIC 32 and generate the control signals S1 to S4. Here, serial data signal can refer to a data signal transmitted by one bit at a time through one signal line or line.

The control signal S1 is a signal for controlling the opening and closing of the switches S61 to S63, S71, and S72 included in the pre-regulator circuit 710. The control signal S2 is a signal for controlling the opening and closing of the switches S11 to S14, S21 to S24, S31 to S34, and S41 to S44 included in the switched-capacitor circuit 720. The control signal S3 is a signal for controlling the opening and closing of the switches S51 to S54 included in the supply modulator 730 when the APT mode is applied to the power amplifier 14. The control signal S4 is a signal for controlling the opening and closing of the switches S56 and S57 for the filter circuits 741 and 742.

A signal line separate from that for the serial data signal is used for the clock signal for processing the serial data signal in the first controller 761, but the configuration is not limited thereto. For example, the clock signal may be transmitted through the same signal line as that for the serial data signal.

Furthermore, in this embodiment, one serial data signal is used to control the pre-regulator circuit 710, the switched-capacitor circuit 720, the supply modulator 730, and the switches S56 and S57, but multiple serial data signals may be used.

The second controller 762 can be configured to process digital control level (DCL) signals (DCL1, DCL2) supplied from the RFIC 32 and generate a control signal S5. The DCL signals are an example of parallel data signals. Here, parallel data signals mean data signals that are transmitted in parallel simultaneously through a plurality of signal lines or circuits.

The DCL signals (DCL1, DCL2) are generated by the RFIC 32 based on an envelope signal of a radio-frequency signal when the D-ET mode is applied to the power amplifier 14. Thus, the control signal S5 is a signal for controlling the opening and closing of the switches S51 to S54 included in the supply modulator 730 when the D-ET mode is applied to the power amplifier 14.

Each of the DCL signals (DCL1, DCL2) is a 1-bit signal according to the exemplary aspect. Moreover, each of the voltages V1 to V4 is represented by a combination of two 1-bit signals. For example, V1, V2, V3, and V4 are represented by “00”, “01”, “10”, and “11”, respectively. Gray code may be used to represent the voltage levels.

Note that in this embodiment, two DCL signals are used to control the supply modulator 730 in the D-ET mode, but the number of DCL signals is not limited to two. For example, one or any number of three or more DCL signals may be used depending on the number of voltage levels that can be selected by each supply modulator 730. Furthermore, the digital control signal used to control the supply modulator 730 is not limited to a DCL signal.

### [4. Power Amplification Method]

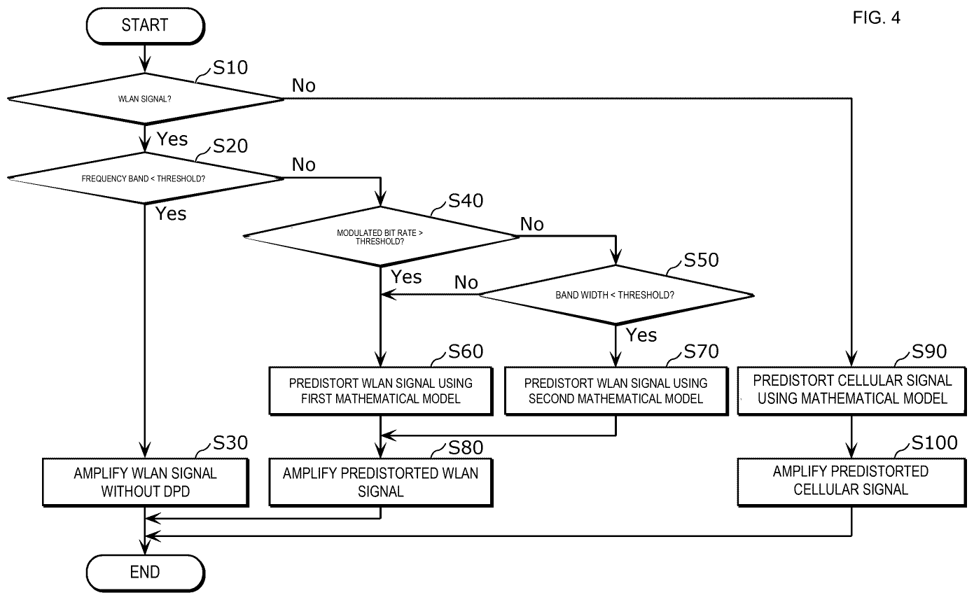

Next, a power amplification method according to this embodiment will be described with reference to FIG. 4. FIG. 4 is a flowchart illustrating the power amplification method according to this embodiment.

First, the RFICs 31 to 33 determine whether the radio-frequency signal to be amplified is a WLAN signal (S10). When the radio-frequency signal to be amplified is a WLAN signal (Yes in S10), the RFIC 31 determines whether the frequency band of the WLAN signal is lower than a threshold band (S20). For example, when the 5 GHz band is used as the threshold band, the 2.4 GHz band is determined to be lower than the 5 GHz band. The threshold band may be one that is experimentally and/or empirically determined in advance.

When the frequency band of the WLAN signal is lower than the threshold band (Yes in S20), the power amplifier 11 amplifies the undistorted WLAN signal (S30). That is, the DPD circuit 311 does not pre-distort the digital IQ signal, and the DAC 312 and the quadrature modulator 313 generate an undistorted WLAN signal from the undistorted digital IQ signals.

On the other hand, when the frequency band of the WLAN signal is not lower than the threshold band (No in S20), the RFIC 31 determines whether the bit rate of the modulation method is higher than a threshold bit rate (S40) and whether the modulation bandwidth is smaller than a threshold width (S50). The threshold bit rate and the threshold width may be experimentally and/or empirically determined in advance.

Here, when the bit rate of the modulation method is higher than the threshold bit rate (Yes in S40) or when the modulation bandwidth is not smaller than the threshold width (No in S50), the DPD circuit 311 pre-distorts the WLAN signal using the first mathematical model incorporating a memory effect (S60). On the other hand, when the bit rate of the modulation method is not higher than the threshold bit rate and the modulation bandwidth is smaller than the threshold width (No in S40 and Yes in S50), the DPD circuit 311 pre-distorts the WLAN signal using the second mathematical model not incorporating a memory effect (S70). Then, the power amplifiers 12 and 13 amplify the pre-distorted WLAN signal (S80).

Note that when the radio-frequency signal to be amplified is not a WLAN signal (No in S10), that is, when the radio-frequency signal to be amplified is a cellular network signal, the DPD circuit 321 or 331 pre-distorts the cellular network signal based on the first mathematical model or the second mathematical model (S90). Then, the power amplifier 14 or 15 amplifies the pre-distorted cellular network signal (S100).

Note that the steps and the order of the steps in FIG. 4 are merely examples, and the power amplification method is not limited to the flowchart in FIG. 4. For example, the order of Steps S40 and S50 may be interchanged. Furthermore, when the power amplification system 20 does not include the RFICs 32 and 33, Step S10 may be skipped. In addition, Steps S40 and S50 may be skipped, and only one of Steps S60 and S70 may be performed.

### [5. Technical Effects]

As described above, the power amplification system 20 according to this embodiment includes the power amplifier 11 configured to amplify a first WLAN signal in a first frequency band, the power amplifier 12 configured to amplify a second WLAN signal in a second frequency band that is higher than the first frequency band, and the DPD circuit 311 configured to pre-distort the second WLAN signal and not pre-distort the first WLAN signal.

Furthermore, the power amplifier circuit 10 according to this embodiment includes the power amplifier 11 configured to amplify a first WLAN signal in a first frequency band, and the power amplifier 12 configured to amplify a second WLAN signal in a second frequency band that is higher than the first frequency band, and the second WLAN signal is pre-distorted and the first WLAN signal is not pre-distorted.

The power amplification method according to this embodiment amplifies a first WLAN signal in a first frequency band that is not pre-distorted (S30), pre-distorts a second WLAN signal in a second frequency band that is higher than the first frequency band (S60 or S70), and amplifies the pre-distorted second WLAN signal (S80).

Thus, by pre-distorting the second WLAN signal in the higher second frequency band, the nonlinear distortion of the second WLAN signal can be reduced and the quality of the transmission signal can be improved. On the other hand, the power consumption for DPD can be reduced by not pre-distorting the lower first WLAN signal. A wider modulation bandwidth is more likely to be used in the higher second frequency band than in the first frequency band, and the nonlinear distortion due to power amplification is large. Furthermore, the bit rate of the modulation method is more likely to be higher in the second frequency band than in the first frequency band, and there is a high demand to reduce the EVM. Therefore, the effect of reducing the nonlinear distortion by pre-distorting the second WLAN signal is large. Conversely, a modulation method with a smaller modulation bandwidth and a lower bit rate is more likely to be used in the lower first frequency band than in the second frequency band, and the effect of reducing nonlinear distortion by pre-distorting the first WLAN signal is small. Therefore, by not pre-distorting the lower first WLAN signal and pre-distorting the second WLAN signal of the higher second frequency band, the quality of the transmission signal is effectively improved while an increase in power consumption in the WLAN is suppressed.

Furthermore, for example, in the power amplification system 20, the power amplifier circuit 10, or the power amplification method according to this embodiment, the first frequency band may include the 2.4 GHz band, and the second frequency band may include at least one of the 5 GHz band, the 6 GHz band, and the 7 GHz band.

Accordingly, by not pre-distorting the first WLAN signal of the 2.4 GHz band and pre-distorting the second WLAN signal of the 5 GHz, 6 GHz, or 7 GHz band, the quality of the transmission signal is effectively improved while an increase in power consumption in the WLAN is suppressed.

For example, the power amplification system 20 according to this embodiment may further include the power amplifier 13 configured to amplify a third WLAN signal in a third frequency band higher than the second frequency band, and the DPD circuit 311 may be further configured to pre-distort the third WLAN signal.

For example, the power amplifier circuit 10 according to this embodiment may further include the power amplifier 13 configured to amplify a third WLAN signal of a third frequency band higher than the second frequency band, and the third WLAN signal may be pre-distorted.

For example, in the power amplification method, the third WLAN signal in the third frequency band that is higher than the second frequency band may be pre-distorted (S60 or S70), and the pre-distorted third WLAN signal may be amplified (S80).

Thus, the nonlinear distortion of the third WLAN signal in the higher third frequency band can be reduced and the quality of the transmission signal by pre-distorting the third WLAN signal can be improved. A wider modulation bandwidth is more likely to be used in the third frequency band, which is higher than the second frequency band. Since the nonlinear distortion caused by power amplification is large in the third frequency band, the effect of reducing the nonlinear distortion by pre-distorting the third WLAN signal is large. Therefore, by pre-distorting the third WLAN signal in the third frequency band, the quality of a transmission signal in the WLAN is effectively improved.

For example, in the power amplification system 20, the power amplifier circuit 10, or the power amplification method according to this embodiment, the third frequency band may include the 60 GHz band.

Accordingly, by pre-distorting the third WLAN signal of the 60 GHz band, the quality of a transmission signal in the WLAN is effectively improved.

For example, the power amplification system 20 according to this embodiment may further include the power amplifier 14 configured to amplify a cellular network signal and the DPD circuit 321 configured to pre-distort the cellular network signal.

For example, the power amplifier circuit 10 according to this embodiment may further include the power amplifier 14 configured to amplify a cellular network signal, and the cellular network signal may be pre-distorted.

For example, the power amplification method according to this embodiment may further include pre-distorting a cellular network signal (S90) and amplifying the cellular network signal that has been pre-distorted (S100).

Thus, by pre-distorting a cellular network signal, the quality of the transmission signal is effectively improved in a cellular network as well.

For example, the power amplification system 20 according to this embodiment may further include the digital envelope tracker 71 configured to generate a plurality of discrete voltages from an input voltage supplied from the DC power source 70 and selectively supply at least one of the plurality of discrete voltages to the power amplifier 14, and the input voltage may be supplied to the power amplifiers 11 and 12 from the DC power source 70.

Thus, the power amplifier 14 that amplifies a cellular network signal is supplied with a plurality of discrete voltages by the digital envelope tracker 71, and as a result, power efficiency is improved. On the other hand, since the power amplifiers 11 and 12 that amplify a WLAN signal are supplied with an input voltage directly from the DC power source 70, the number of components can be reduced and the communication device 60 can be reduced in size. In particular, since a larger output power is required for a cellular network signal than for a WLAN signal, the effect of improving power efficiency is large.

Furthermore, for example, in the power amplification system 20 according to this embodiment, the DPD circuit 311 may switch the mathematical model used for DPD of the second WLAN signal based on at least one of the modulation method and the modulation bandwidth of the second WLAN signal.

Thus, by switching the mathematical model depending on the modulation method and modulation bandwidth, it is possible to prioritize reduction of the calculation load for DPD (i.e., reduction of power consumption) or reduction of nonlinear distortion. Since the required value of EVM and the amount of nonlinear distortion vary depending on the modulation method and modulation bandwidth, switching the mathematical model in accordance with the modulation method and modulation bandwidth is an effective way of improving the quality of the transmission signal while an increase in power consumption is suppressed.

For example, in the power amplification system 20 according to this embodiment, the DPD circuit 311 may pre-distort the second WLAN signal using the first mathematical model incorporating the memory effect of the power amplifier 12 when the bit rate of the modulation method of the second WLAN signal is higher than a threshold bit rate, and may pre-distort the second WLAN signal using the second mathematical model not incorporating the memory effect of the power amplifier 12 when the bit rate of the modulation method of the second WLAN signal is not higher than the threshold bit rate.

Thus, when the bit rate of the modulation method is higher, the first mathematical model incorporating the memory effect is used, so that the reduction of nonlinear distortion can be prioritized, and the quality of the transmission signal are effectively improved. On the other hand, when the bit rate of the modulation method is lower, the second mathematical model not incorporating the memory effect is used, so that the reduction of the calculation load can be prioritized, and an increase in power consumption are suppressed. When the bit rate of the modulation method is high, since the required value for EVM is also high, it is effective to use the first mathematical model that greatly reduces nonlinear distortion when the bit rate of the modulation method is high.

For example, in the power amplification system 20 according to this embodiment, the DPD circuit 311 may pre-distort the second WLAN signal using the first mathematical model incorporating the memory effect of the power amplifier 12 when the modulation bandwidth of the second WLAN signal is larger than a threshold bandwidth, and may pre-distort the second WLAN signal using the second mathematical model not incorporating the memory effect of the power amplifier 12 when the modulation bandwidth of the second WLAN signal is not larger than the threshold bandwidth.

Thus, when the modulation bandwidth is larger, the first mathematical model incorporating the memory effect is used, so that the reduction of nonlinear distortion can be prioritized, and the quality of the transmission signal is effectively improved. On the other hand, when the modulation bandwidth is smaller, the second mathematical model not incorporating the memory effect is used, so that the reduction of the calculation load can be prioritized, and an increase in power consumption is suppressed. When the modulation bandwidth is larger, the peak to average power ratio (PAPR) increases and the nonlinear distortion also increases, and therefore it is effective to use the first mathematical model that greatly reduces nonlinear distortion when the modulation bandwidth is larger.

### Additional Exemplary Embodiments

The power amplification system, the power amplifier circuit, and the power amplification method according to the exemplary aspects of the present disclosure have been described above based on embodiments, but the power amplification system, the power amplifier circuit, and the power amplification method described herein are not limited to the above-described embodiments. Other embodiments realized by combining any of the components of the above embodiments, modifications obtained by modifying the above embodiments in various ways that a person skilled in the art can conceive of without departing from the spirit of the present disclosure, and various devices incorporating the above-described power amplification system or power amplifier circuit are also included in the present disclosure.

For example, in the circuit configurations of the various circuits according to the above embodiments, other circuit elements, wiring lines, etc. may be inserted between the paths connecting the circuit elements and signal paths disclosed in the drawings. For example, a filter may be inserted between a DAC and a quadrature modulator. In addition, for example, a filter may be inserted between a power amplifier and an antenna.

Note that in the above embodiments, multiple discrete voltages are supplied to the supply modulator from the switched-capacitor circuit, but the configuration is not limited thereto. For example, multiple discrete voltages may be supplied to the supply modulator from multiple DCDC converters. In addition, when the voltage levels of the multiple discrete voltages are equally spaced, a switched-capacitor circuit can be used to effectively reduce the size of a tracker module.

In addition, in each of the above embodiments, the power amplifier circuit does not include a receive path, but the power amplifier circuit may include a receive path.

It should be appreciated that the exemplary aspects of the present disclosure can be widely used in communication devices such as mobile phones as a power amplification system for amplifying radio-frequency signals.

### REFERENCE SIGNS LIST

10 power amplifier circuit
11, 12, 13, 14, 15 power amplifier
20 power amplification system
31, 32, 33 RFIC
41, 42, 43 BBIC
51, 52, 53, 54, 55 antenna
60 communication device
70 DC power source
71 digital envelope tracker
72 average power tracker
110, 131, 132, 133, 134 input terminal
111, 112, 113, 114, 130 output terminal
311, 321, 331 DPD circuit
312, 322, 332 DAC
313, 323, 333 quadrature modulator
710 pre-regulator circuit
720 switched-capacitor circuit
730 supply modulator
741, 742 filter circuit
760 digital control circuit
761 first controller
762 second controller

1. A power amplification system comprising:
a first power amplifier configured to amplify a first wireless local area network signal in a first frequency band;
a second power amplifier configured to amplify a second wireless local area network signal in a second frequency band that is higher than the first frequency band; and
a first digital pre-distortion circuit configured to pre-distort the second wireless local area network signal and to not pre-distort the first wireless local area network signal.

2. The power amplification system according to claim 1,
wherein the first frequency band comprises a 2.4 GHz band, and
the second frequency band comprises at least one of a 5 GHz band, a 6 GHz band, and a 7 GHz band.

3. The power amplification system according to claim 1, further comprising:
a third power amplifier configured to amplify a third wireless local area network signal in a third frequency band that is higher than the second frequency band,
wherein the first digital pre-distortion circuit is further configured to pre-distort the third wireless local area network signal.

4. The power amplification system according to claim 3, wherein the third frequency band comprises a 60 GHz band.

5. The power amplification system according to claim 1, wherein the first digital pre-distortion circuit is configured to switch a mathematical model used for digital pre-distortion of the second wireless local area network signal based on at least one of a modulation method and a modulation bandwidth of the second wireless local area network signal.

6. The power amplification system according to claim 5,
wherein the first digital pre-distortion circuit is configured to pre-distort the second wireless local area network signal using a first mathematical model that incorporates a memory effect of the second power amplifier when a bit rate of the modulation method of the second wireless local area network signal is higher than a threshold bit rate, and
wherein the first digital pre-distortion circuit is further configured to pre-distort the second wireless local area network signal using a second mathematical model that does not incorporate the memory effect of the second power amplifier when the bit rate of the modulation method of the second wireless local area network signal is not higher than the threshold bit rate.

7. The power amplification system according to claim 5,
wherein the first digital pre-distortion circuit is configured to pre-distort the second wireless local area network signal using a first mathematical model that incorporates a memory effect of the second power amplifier when the modulation bandwidth of the second wireless local area network signal is larger than a threshold bandwidth, and
wherein the first digital pre-distortion circuit is further configured to pre-distort the second wireless local area network signal using a second mathematical model that does not incorporate the memory effect of the second power amplifier when the modulation bandwidth of the second wireless local area network signal is not larger than the threshold bandwidth.

8. The power amplification system according to claim 1, further comprising:
a fourth power amplifier configured to amplify a cellular network signal; and
a second digital pre-distortion circuit configured to pre-distort the cellular network signal.

9. The power amplification system according to claim 8, further comprising:
a tracker circuit configured to generate a plurality of discrete voltages from an input voltage supplied from a DC power source and to selectively supply at least one discrete voltage of the plurality of discrete voltages to the fourth power amplifier,
wherein the first power amplifier and the second power amplifier are supplied with the input voltage from the DC power source.

10. A power amplifier circuit comprising:
a first power amplifier configured to amplify a first wireless local area network signal in a first frequency band; and
a second power amplifier configured to amplify a second wireless local area network signal in a second frequency band that is higher than the first frequency band,
wherein the second wireless local area network signal is pre-distorted, and
the first wireless local area network signal is not pre-distorted.

11. The power amplifier circuit according to claim 10,
wherein the first frequency band comprises a 2.4 GHz band, and
the second frequency band comprises at least one of a 5 GHz band, a 6 GHz band, and a 7 GHz band.

12. The power amplifier circuit according to claim 10, further comprising:
a third power amplifier configured to amplify a third wireless local area network signal in a third frequency band that is higher than the second frequency band,
wherein the third wireless local area network signal is pre-distorted.

13. The power amplifier circuit according to claim 12, wherein the third frequency band comprises a 60 GHz band.

14. The power amplifier circuit according to claim 10, further comprising a fourth power amplifier configured to amplify a cellular network signal that is pre-distorted.

15. The power amplifier circuit according to claim 14,
wherein a digital envelope tracking (D-ET) mode is applied to the fourth power amplifier, and
a fixed voltage mode is applied to the first power amplifier and the second power amplifier.

16. A power amplification method comprising:
amplifying a first wireless local area network signal in a first frequency band that is not pre-distorted;
pre-distorting a second wireless local area network signal in a second frequency band that is higher than the first frequency band; and
amplifying the pre-distorted second wireless local area network signal.

17. The power amplification method according to claim 16,
wherein the first frequency band comprises a 2.4 GHz band, and
the second frequency band comprises at least one of a 5 GHz band, a 6 GHz band, and a 7 GHz band.

18. The power amplification method according to claim 16, further comprising:
pre-distorting a third wireless local area network signal in a third frequency band that is higher than the second frequency band; and
amplifying the pre-distorted third wireless local area network signal.

19. The power amplification method according to claim 18, wherein the third frequency band comprises a 60 GHz band.

20. The power amplification method according to claim 16, further comprising:
pre-distorting a cellular network signal; and
amplifying the pre-distorted cellular network signal.
